(19) United States
(12) Patent Application Publication
(10) Pub. No.: US 2021/0371274 A1
(43) Pub. Date: Dec. 2, 2021

(54) DEEP CAVITY ETCHING METHOD

(71) Applicant: AAC ACOUSTIC TECHNOLOGIES (SHENZHEN) CO., LTD., Shenzhen (CN)

(72) Inventors: Xiaohui Zhong, Singapore (SG); Yan Hong, Shenzhen (CN); Rui Zhang, Shenzhen (CN); Kahkeen Lai, Singapore (SG); Lanlan Tu, Shenzhen (CN)

(21) Appl. No.: 17/137,356

(22) Filed: Dec. 30, 2020

(30) Foreign Application Priority Data
May 27, 2020 (CN) 202010464271.8

(51) Int. Cl. B81C 1/00

(52) U.S. Cl. CPC B81C 1/00404; B81C 2201/0198; B81C 2201/0133

(57) ABSTRACT

A deep cavity etching method is disclosed. The deep cavity includes a large cavity and a small cavity forming a step. The method includes the following steps: providing a silicon substrate containing at least an upper surface; forming an oxide layer on the upper surface of the silicon substrate; and coating the first photoresist on the side of the oxide layer away from the silicon substrate. The deep cavity of the step avoids the photoresist spraying process with higher efficiency and lower cost, reduces the process cost and improves the production capacity.

### FIELD OF THE PRESENT DISCLOSURE

The invention relates to the technical field of etching, in particular to a deep cavity etching method.

### DESCRIPTION OF RELATED ART

In a micro-electro-mechanical systems (MEMS) device forming process, a deep cavity with stairs needs to be etched. The surface of a substrate needs to be coated with photoresists during etching. The deep cavity has depth differences for the stairs, if the photoresists are coated only through a spin-coating process, the photoresists tend to aggregate at the lowest point on the surface of the substrate to cause uneven coating on the surface of the substrate due to the influences of fluidity and gravity in the spin-coating process; therefore, in the prior art, the deep cavity with the stairs is usually etched by adopting a mode of combining spin-rotating with spraying, a large cavity is etched through spin-rotating coating, and then small cavities are etched through spraying coating.

Although the spraying coating mode can ensure that the photoresists are evenly coated on the surface with height differences, the spraying coating mode is lower in efficiency and higher in cost compared with the spin-rotating coating. Therefore, in order to further reduce the etching cost and improve the production capacity, it is necessary to provide a method capable of etching the deep cavity with the stairs only through the spin-rotating coating.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is a flowchart of a method of the invention.

FIG. 2 is a sectional structure diagram in a step S10 of the invention.

FIG. 3 is the sectional structure diagram in steps S20 to S30 of the invention.

FIG. 4 is the sectional structure diagram from which a first photoresist is removed after the step S30 of the invention.

FIG. 5 is the sectional structure diagram in steps S40 to S50 of the invention.

FIG. 6 is the sectional structure diagram in a step S60 of the invention.

FIG. 7 is the sectional structure diagram from which a pattern oxide layer is removed after the step S60 of the invention.

### DETAILED DESCRIPTION OF THE EXEMPLARY EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby is only to explain the disclosure, not intended to limit the disclosure.

The embodiment provides a deep cavity etching method. A deep cavity comprises a big cavity 73 and small cavities 74 for forming stairs 75 with the large cavity 73; the small cavities 74 are positioned in the large cavity 73, and each stair 75 is formed by a height difference between the large cavity 73 and one small cavity 74.

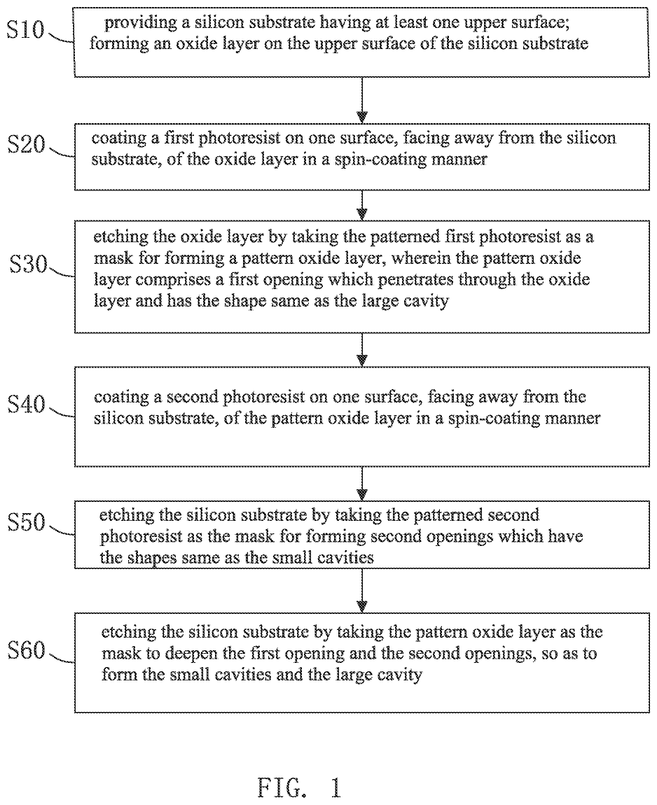

Referring to FIG. 1, the method comprises the following steps:

S10, a silicon substrate 30 which comprises at least one upper surface 31 is provided; and an oxide layer 40 is formed on the upper surface 31 of the silicon substrate 30.

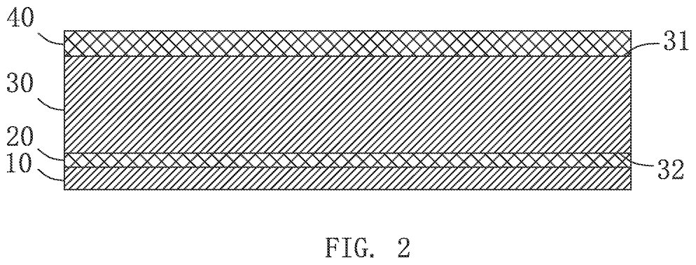

More preferably, referring to FIG. 2, the silicon substrate 30 comprises the upper surface 31 and a lower surface 32 opposite to the upper surface 31, the upper surface is an upward surface in FIG. 2, and the lower surface 32 is a downward surface in FIG. 2. In the embodiment, the oxide layer is formed on the upper surface 31 of the silicon substrate 30; a cutoff layer 20 is formed on the lower surface 32 of the silicon substrate 30; the cutoff layer 20 is silicon dioxide formed by thermal oxidation of the lower surface 32; a layer of device structure 10 is arranged on one surface, facing away from the silicon substrate 30, of the cutoff layer 20; and the layer of device structure 10 is one of monocrystalline silicon or polycrystalline silicon. In the embodiment, the layer of device structure 10 is the monocrystalline silicon.

Specifically, the silicon substrate 30 is provided as a substrate. In the embodiment, a polycrystalline silicon material is adopted by the silicon substrate 30, and the polycrystalline silicon material is one of crystalline silicon, but not limited to the crystalline silicon as a substrate material.

More preferably, the upper surface 31 and the lower surface 32 are planes, so as to carry out a spin-coating coating process on the upper surface 31.

Specifically, the oxide layer 40 is the silicon dioxide formed by thermal oxidation of silicon crystal of the upper surface 31 of the silicon substrate.

More preferably, the thickness of the oxide layer 40 is defined as a and meets the relation: a is smaller than or equal to 10 microns and greater than or equal to 0 microns; more preferably, a meets the relation: a is smaller than or equal to 4 microns and greater than or equal to 2 microns, so that the problem that the uniformity of spin-coating coating of photoresists is affected by a too large height difference between the oxide layer 40 and the silicon substrate 30 is avoided when the silicon substrate 30 is etched by taking the oxide layer 40 as a mask.

S20, a first photoresist 50 is coated on one surface, facing away from the silicon substrate 30, of the oxide layer 40 in a spin-coating manner and is patterned.

More preferably, one surface, facing away from the silicon substrate 30, of the oxide layer 40 is the plane, so as to improve the uniformity of spin-coating coating of the first photoresist 50.

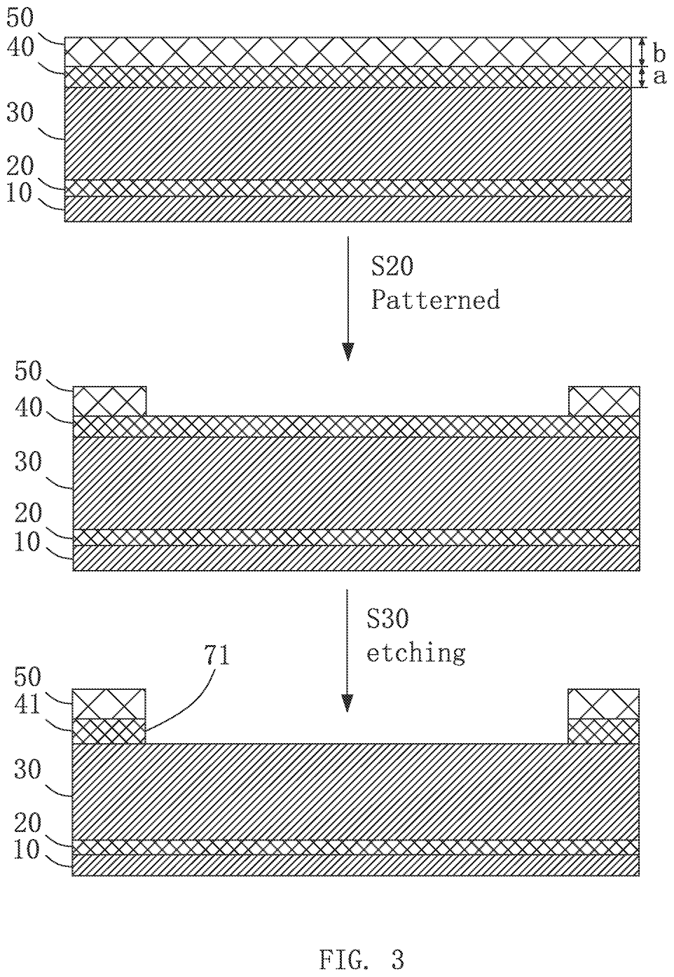

More preferably, referring to FIG. 3, the first photoresist 50 is coated on one surface, facing away from the silicon substrate 30, of the oxide layer 40 through the spin-coating coating process.

More preferably, referring to FIG. 3, the first photoresist 50 is patterned, and the thickness of the first photoresist 50 is defined as b and meets the relation: b is smaller than 10 microns, so as to etch the oxide layer 40 by taking the first photoresist as the mask.

It will be understood that the patterning is transferring preset patterns to the photoresists from a photolithography mask plate through a known exposure and development technique. In the embodiment, the specific process of the patterning is not expanded.

Specifically, the planar contour shape of the large cavity on the photolithography mask plate is transferred to the first photoresist through the patterning, so as to etch a first opening 71 corresponding to the planar contour shape of the large cavity 73 in the oxide layer 40 by taking the patterned first photoresist 50 as the mask.

S30, the oxide layer 40 is etched by taking the patterned first photoresist 50 as the mask to form a pattern oxide layer 41, wherein the pattern oxide layer 41 comprises the first opening 71 which penetrates through the oxide layer 40 and has the shape same as the large cavity 73.

Specifically, referring to FIG. 3, the oxide layer 40 is etched by taking the patterned first photoresist 50 as the mask; an etching solution etches the oxide layer 40 along the direction close to the silicon substrate 30; and the oxide layer 40 is etched to form the pattern oxide layer 41.

More preferably, the pattern oxide layer 41 comprises the first opening 71; the first opening 71 penetrates through the oxide layer 40; and the planar contour shape of the first opening 71 is the same as that of the large cavity 73. In the embodiment, the etching solution for etching corresponding to the oxide layer 40 is adopted as the etching solution, and has a relatively high etching selection ratio of the silicon dioxide to the silicon. The etching solution naturally stops etching when etching through the oxide layer 40 to the silicon substrate 30, and the silicon substrate 30 is prevented from being etched by the etching solution.

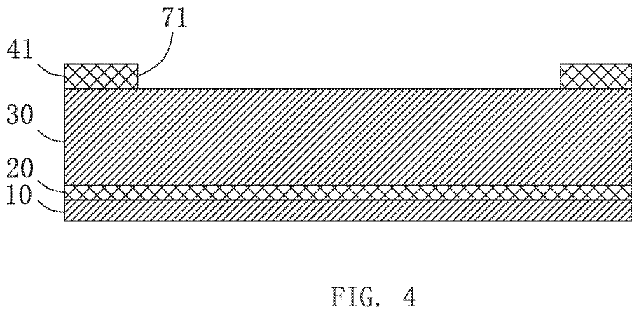

More preferably, referring to FIG. 4, the first photoresist 50 is cleared after the first opening 71 is formed, so as to obtain the pattern oxide layer 41 with the first opening 71 which has the shape same as the large cavity 73.

Specifically, in the embodiment, the etching solution completely etches through the oxide layer, so that the depth of the first opening is equal to the thickness of the oxide layer. In the embodiment, the thickness a of the oxide layer 40 is smaller than or equal to 4 microns and greater than or equal to 2 microns, so that the first opening 71 is a shallow cavity with the height difference of 2-4 microns. Due to the relatively small height difference of the first opening 71, the uniformity of spin-coating coating is improved in subsequent photoresist coating.

S40, a second photoresist 60 is coated on one surface, facing away from the silicon substrate 30, of the pattern oxide layer 41 in a spin-coating manner and is patterned.

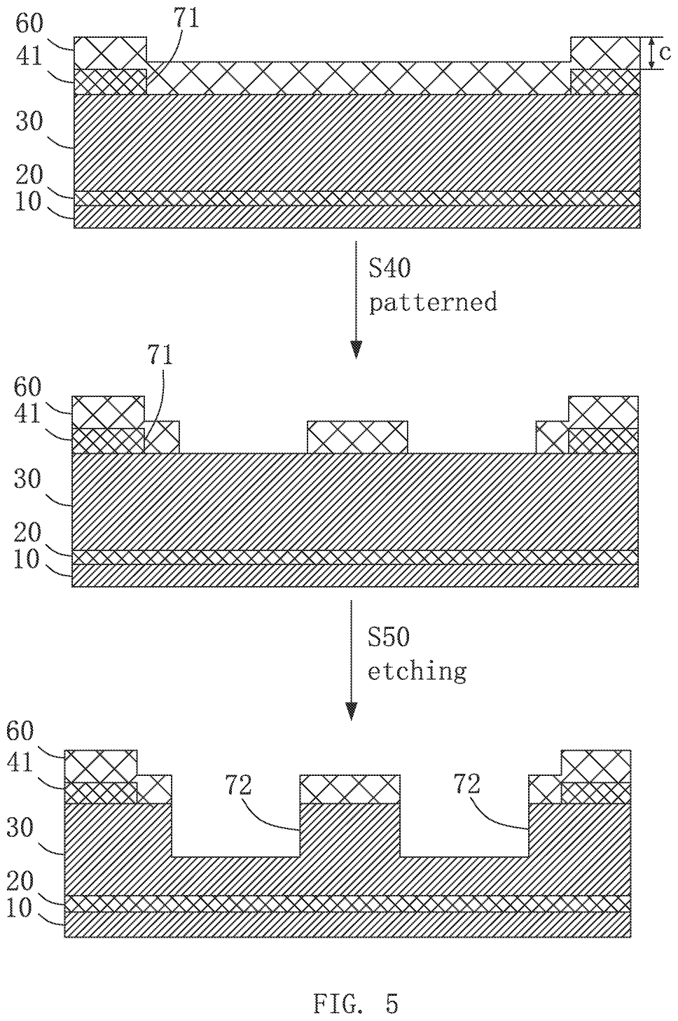

Specifically, referring to FIG. 5, the second photoresist 60 is coated on the pattern oxide layer 41 through the spin-coating process, one part of the second photoresist 60 covers one surface, facing away from the silicon substrate 30, of the pattern oxide layer 41, and the other part of the second photoresist 60 is coated on the silicon substrate 30 through the first opening 71.

More preferably, the second photoresist 60 is patterned, and the thickness of the second photoresist 60 is defined as c and meets the relation: c is smaller than 10 microns, so as to etch the silicon substrate 30 by taking the second photoresist as the mask.

Specifically, the planar contour shapes of the small cavities 74 on the photolithography mask plate are transferred to the second photoresist 60 through the patterning, so as to etch second openings 72 corresponding to the planar contour shapes of the small cavities 74 in the silicon substrate 30 by taking the patterned second photoresist 60 as the mask.

S50, the silicon substrate 30 is etched by taking the patterned second photoresist 60 as the mask to form the second openings 72 which have the shapes same as the small cavities 74.

More preferably, referring to FIG. 5, the silicon substrate 30 is etched by taking the patterned second photoresist 60 as the mask; and the etching solution etches the silicon substrate 30 along the direction close to the cutoff layer 20.

Specifically, the silicon substrate 30 is etched by taking the patterned second photoresist 60 as the mask. The etching solution etches the silicon substrate 30 through the patterned second photoresist 60; the etching solution etches the silicon substrate 30 to form the second openings 72; the second openings 72 are positioned in the first opening 71. The second openings 72 do not penetrate through the silicon substrate 30; and the planar contour shapes of the second openings 72 are the same as those of the small cavities 74.

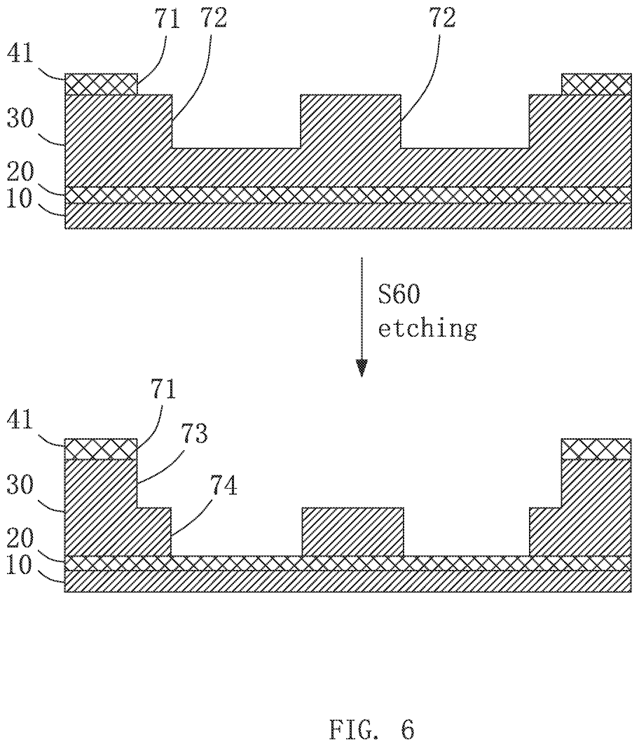

More preferably, referring to FIG. 6, the second photoresist 60 is cleared to carry out a step S60 after the second openings 72 are formed.

S60, the silicon substrate 30 is etched by taking the pattern oxide layer 41 as the mask to deepen the first opening 71 and the second openings 72, so as to form the small cavities 74 and the large cavity 73.

Specifically, referring to FIG. 6, the silicon substrate 30 is etched by taking the pattern oxide layer 41 as the mask. The etching solution etches the silicon substrate 30 through the first opening 71 and the second openings 72; and the etching solution etches the silicon substrate 30 under the constraint of the pattern oxide layer 41, etches the silicon substrate 30 to form the large cavity 73 on the basis of the first opening 71, and simultaneously etches the silicon substrate 30 to form the small cavities 74 on the basis of the second openings 72.

More preferably, in the embodiment, the etching solution stops etching when etching the silicon substrate 30 to the cutoff layer 20, so as to form the large cavity 73 and the small cavities 74, and at the moment, the small cavities 74 penetrate through the silicon substrate 30. Of course, in other alternative embodiments, the cutoff layer 20 may not be arranged, and the etching speed and stopping are controlled only by controlling the parameters, such as the concentration of the etching solution or the etching time.

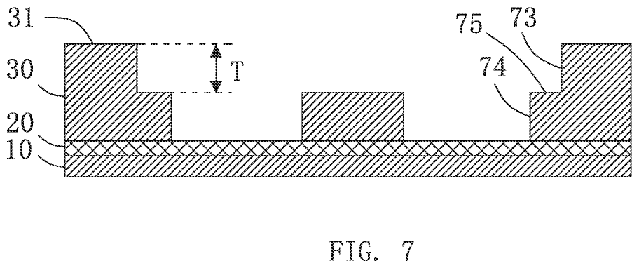

More preferably, referring to FIG. 7, the pattern oxide layer 41 is cleared after the step S60, so as to obtain a preset deep cavity comprising the large cavity 73 and the small cavities 74 for forming the stairs.

More preferably, the depth of the large cavity is defined as T and meets the relation: T is greater than 50 microns. Since the large cavity 73 and the small cavities 74 are etched at the same time, the large cavity is the deep cavity of which the depth is greater than 50 microns, and does not affect the photoresist spin-coating coating process when the small cavities are formed. Therefore, etching of the deep cavity comprising the large cavity 73 and the small cavities 74 for forming the stairs 75 with the large cavity 73 can be implemented only by adopting the photoresist spin-coating coating process twice in the step S20 and the step S40. The photoresist spin-coating coating process is adopted twice, so that a photoresist spraying process is avoided, the process cost is greatly reduced and the process efficiency is improved.

More preferably, the number of the first openings 71 is the same as that of the large cavities 73 and is plural; and the number of the second openings 72 is the same as that of the small cavities 74 and is plural. In the embodiment, the number of the first opening 71 and the number of the large cavity 73 are one; and the number of the second openings 72 and the number of the small cavities 74 are two.

Thereby, through forming the patterned pattern oxide layer 41 on the upper surface 31 of the silicon substrate 30 as the mask of etching the silicon substrate 30, the deep cavity with the stairs 75 can be etched and formed only by adopting spin-coating coating twice, so that the photoresist spraying process with higher cost and lower efficiency is avoided, the process cost is reduced and the production capacity is improved.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A deep cavity etching method, wherein a deep cavity comprises a big cavity and small cavities for forming stairs with the large cavity; and the deep cavity etching method comprises steps of:
providing a silicon substrate having at least one upper surface;
forming an oxide layer on the upper surface of the silicon substrate, wherein a thickness of the oxide layer is smaller than or equal to 10 microns;
coating a first photoresist on one surface, facing away from the silicon substrate, of the oxide layer in a spin-coating manner;
etching the oxide layer by taking the patterned first photoresist as a mask for forming a pattern oxide layer, wherein the pattern oxide layer comprises a first opening which penetrates through the oxide layer and has the shape same as the large cavity;
coating a second photoresist on one surface, facing away from the silicon substrate, of the pattern oxide layer in a spin-coating manner;
etching the silicon substrate by taking the patterned second photoresist as the mask for forming second openings which have the shapes same as the small cavities; and
etching the silicon substrate by taking the pattern oxide layer as the mask to deepen the first opening and the second openings, so as to form the small cavities and the large cavity.

2. The deep cavity etching method according to claim 1, wherein the thickness of the oxide layer is smaller than or equal to 4 microns and greater than or equal to 2 microns.

3. The deep cavity etching method according to claim 1, wherein a depth of the large cavity is greater than 50 microns.

4. The deep cavity etching method according to claim 1, wherein the silicon substrate further comprises a lower surface arranged opposite to the upper surface; and a cutoff layer is formed on one surface, far away from the upper surface, of the lower surface.

5. The deep cavity etching method according to claim 4, wherein the silicon substrate is etched by taking the pattern oxide layer as the mask to deepen the first opening and the second openings to the cutoff layer, so as to form the small cavities and the large cavity.

6. The deep cavity etching method according to claim 5, wherein a layer of device structure is arranged on one surface, facing away from the silicon substrate, of the cutoff layer.

7. The deep cavity etching method according to claim 4, wherein the silicon substrate is polycrystalline silicon.

8. The deep cavity etching method according to claim 7, wherein the cutoff layer is formed by thermal oxidation of the lower surface.

9. The deep cavity etching method according to claim 1, wherein the number of the first openings is the same as that of the large cavities and is plural.

10. The deep cavity etching method according to claim 1, wherein the number of the second openings is the same as that of the small cavities and is plural.
